(19) United States
(12) Patent Application Publication
(10) Pub. No.: US 2012/0064720 A1
(43) Pub. Date: Mar. 15, 2012

(54) PLANARIZATION CONTROL FOR SEMICONDUCTOR DEVICES

(75) Inventors: Neng-Kuo Chen, Sinshih Township (TW); Jeff J. Xu, Jhubei City (TW)

(73) Assignee: TAIWAN SEMICONDUCTOR MANUFACTURING COMPANY, LTD., Hsin-Chu (TW)

(21) Appl. No.: 12/879,664

(22) Filed: Sep. 10, 2010

(51) Int. Cl. H01L 21/306; B05C 11/00; C23F 1/08

(52) U.S. Cl. 438/692; 156/345.1; 118/75; 257/E21.23

(57) ABSTRACT

Provided is a method of planarizing a semiconductor device. The method includes providing a substrate. The method includes forming a first material layer on the substrate. The method includes forming a second material layer over the first material layer. The second material layer is softer than the first material layer and has an exposed surface that is not in contact with the first material layer. The method includes flattening the second material layer without removing a portion of the second material layer. The flattening is carried out in a manner such that the exposed surface is substantially flat after the flattening. The method includes performing an etch back process to remove the second material layer and a portion of the first material layer. Wherein an etching selectivity of the etch back process with respect to the first and second material layers is approximately 1:1.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs. In the course of integrated circuit evolution, functional density (i.e., the number of interconnected devices per chip area) has generally increased while geometry size (i.e., the smallest component that can be created using a fabrication process) has decreased. This scaling down process generally provides benefits by increasing production efficiency and lowering associated costs.

As semiconductor device sizes continue to shrink, it has become increasingly more difficult to meet device planarization requirements in fabrication. Conventional planarization methods typically involve performing a chemical-mechanical-polishing (CMP) process on a semiconductor wafer. However, these traditional planarization methods have not been able to achieve satisfactory performance for newer technology nodes such as the 15 nanometer (nm) technology node and beyond.

Therefore, while existing methods of semiconductor device planarization control have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method for planarizing a semiconductor device according to various aspects of the present disclosure.

FIGS. 2-6 are diagrammatic fragmentary cross-sectional side views of a semiconductor device at various stages of fabrication in accordance with an embodiment of the method illustrated in FIG. 1.

FIGS. 7-9 are diagrammatic fragmentary cross-sectional side views of a semiconductor device at various stages of fabrication in accordance with an alternative embodiment of the method illustrated in FIG. 1.

FIG. 10 is a block diagram of a system that can be used to carry out the method illustrated in FIG. 1.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for the sake of simplicity and clarity.

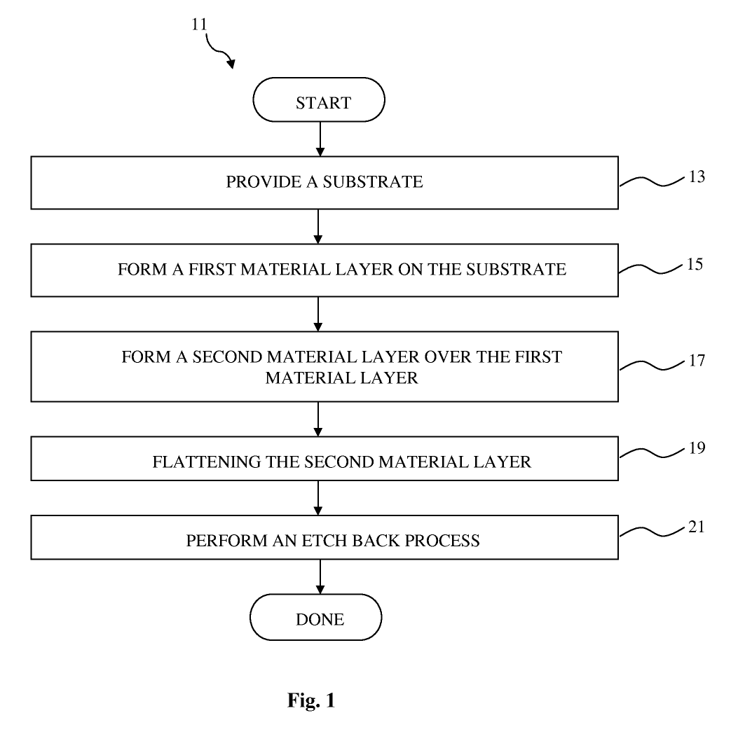

Illustrated in FIG. 1 is a flowchart of a method 11 for planarizing a semiconductor device according to various aspects of the present disclosure. Referring to FIG. 1, the method 11 begins with block 13 in which a semiconductor substrate is provided. The method continues with block 15 in which a first material layer is formed on the substrate. The method continues with block 17 in which a second material layer is formed over the first material layer. The second material layer is softer than the first material layer and has an exposed upper surface that is not in contact with the first material layer. The method continues with block 19 in which the second material layer is flattened without removing a portion of the second material. The flattening is carried out in a manner such that the exposed surface is substantially planar after the flattening. The method continues with block 21 in which an etch back process is performed to remove the second material layer and a portion of the first material layer. The etching selectivity of the etch back process with respect to the first and second material layers is approximately 1:1.

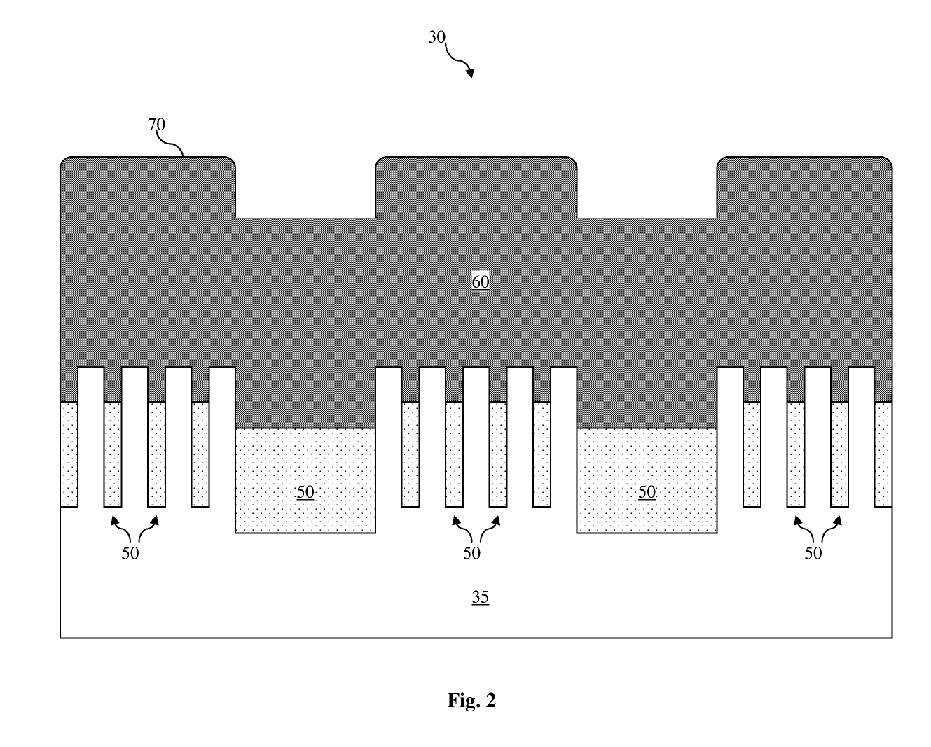

FIGS. 2 to 6 are diagrammatic fragmentary cross-sectional side views of a portion of a semiconductor device 30 at various fabrication stages according to an embodiment of the method 11 of FIG. 1. As an example, the semiconductor device 30 illustrated in FIGS. 2-6 is a portion of a semiconductor wafer. It is understood that FIGS. 2 to 6 have been simplified for a better understanding of the inventive concepts of the present disclosure.

Referring to FIG. 2, the semiconductor device 30 includes a substrate 35. The substrate 35 is a silicon substrate doped with either a P-type dopant such as boron, or doped with an N-type dopant such as phosphorous or arsenic. The substrate 35 may alternatively include other elementary semiconductors such as germanium and diamond. The substrate 35 may optionally include a compound semiconductor and/or an alloy semiconductor. Further, the substrate 35 may include an epitaxial layer (epi layer), may be strained for performance enhancement, and may include a silicon-on-insulator (SOI) structure.

Openings may be formed in the substrate 35, and a dielectric material 50 is formed to at least partially fill these openings. The dielectric material 50 may be formed using a deposition process known in the art, such as a chemical vapor deposition (CVD) process, a physical vapor deposition (PVD) process, an atomic layer deposition (ALD) process, combinations thereof, or another suitable process. In an embodiment, the dielectric material 50 includes an oxide material.

A material layer 60 is then formed over the dielectric material 50. The material layer 60 may be formed by a deposition process such as CVD, PVD, ALD, combinations thereof, or another suitable process. In an embodiment, the material layer 60 includes a polysilicon material. The polysilicon material may be used later to form various components of the semiconductor device 30, such as a polysilicon gate for a Field Effect Transistor (FET) device.

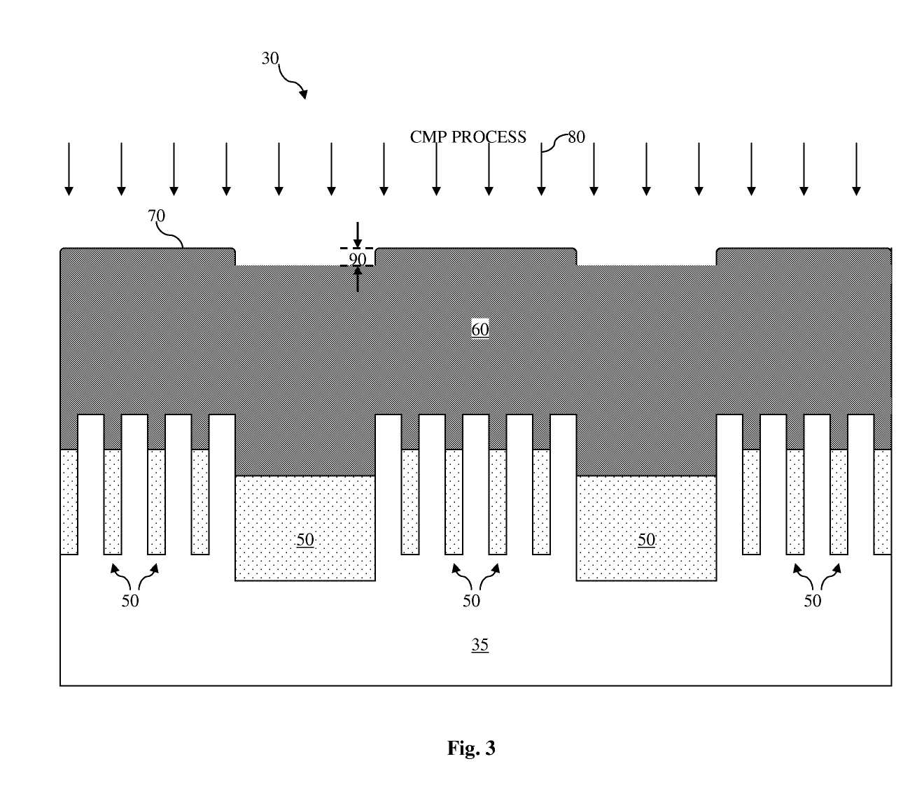

At this stage of fabrication, the material layer 60 may not be flat enough for the later fabrication processes. Often times, an exposed surface 70 (or upper surface) of the material layer 60 may be uneven, rough, and may have bumps after the deposition. Subsequent fabrication processes may require the surface 70 to be relatively flat and smooth. Thus, referring to FIG. 3, a chemical-mechanical-polishing (CMP) process 80 may be optionally performed on the semiconductor device 30 to make the surface 70 flatter or more planar.

However, even after the CMP process 80, the surface 70 of the material layer 60 may still not be flat enough for subsequent processes. To illustrate, as shown in FIG. 3, the surface 70 may have a total surface variation 90. The total surface variation 90 measures the flatness of the surface 70. As an example, the total surface variation 90 may be defined as the difference (or variation) between the highest point (farthest away from the substrate 35) and the lowest point of the surface 70 (closest to the substrate 35). Often times, the total surface variation 90 exceeds what is acceptable for subsequent fabrication processes. Thus, according to various aspects of the present disclosure, the processes described below will further reduce the total surface variation 90 to make the surface 70 more planar.

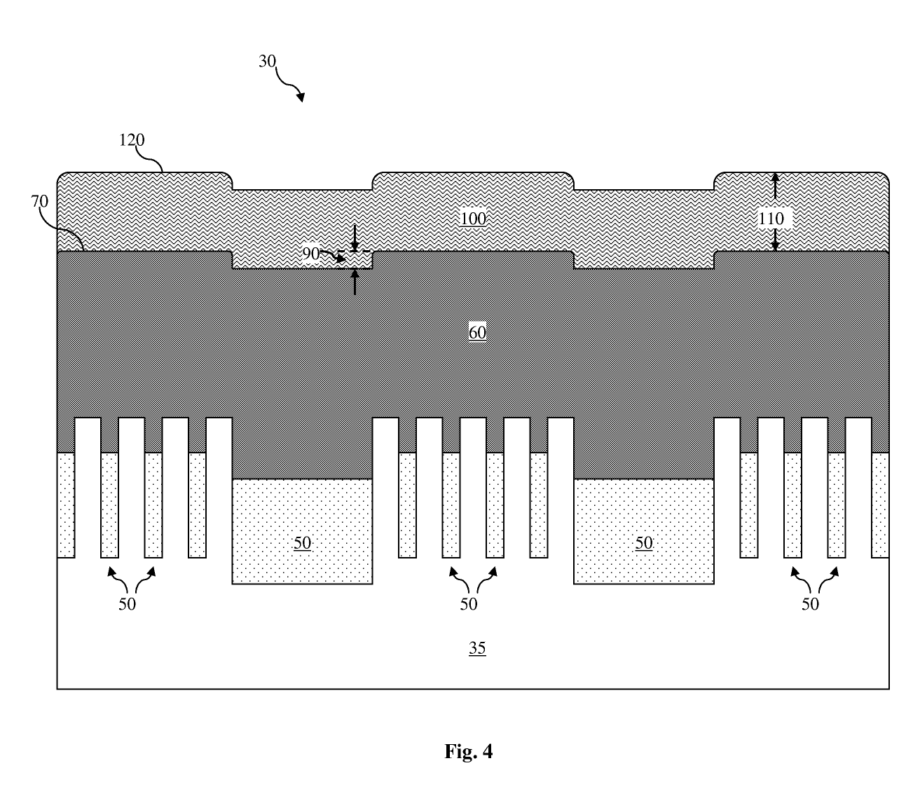

Referring to FIG. 4, a material layer 100 is formed over the material layer 60. In an embodiment, the material layer 100 is formed in an approximately conformal manner to the upper surface 70 of the material layer 60. The material layer 100 includes a soft and malleable (or moldable) material. The material layer 100 is softer than the material layer 60. In an embodiment, the material layer 100 includes a photoresist material, which may be formed by a spin-coating process known in the art. In that case, the photoresist material has not been hard baked yet, therefore it remains soft.

The material layer 100 has a thickness 110 that is greater than the total surface variation 90 of the surface 70. In an embodiment, the thickness 110 is in a range from about 500 angstroms to about 1500 angstroms. The material layer 100 has an exposed surface 120, also referred to as an upper surface. In an alternative embodiment, the material layer 100 may be formed on the material layer 60 before the CMP process 80 (shown in FIG. 3) is performed, in which case the CMP process 80 may not be performed at all.

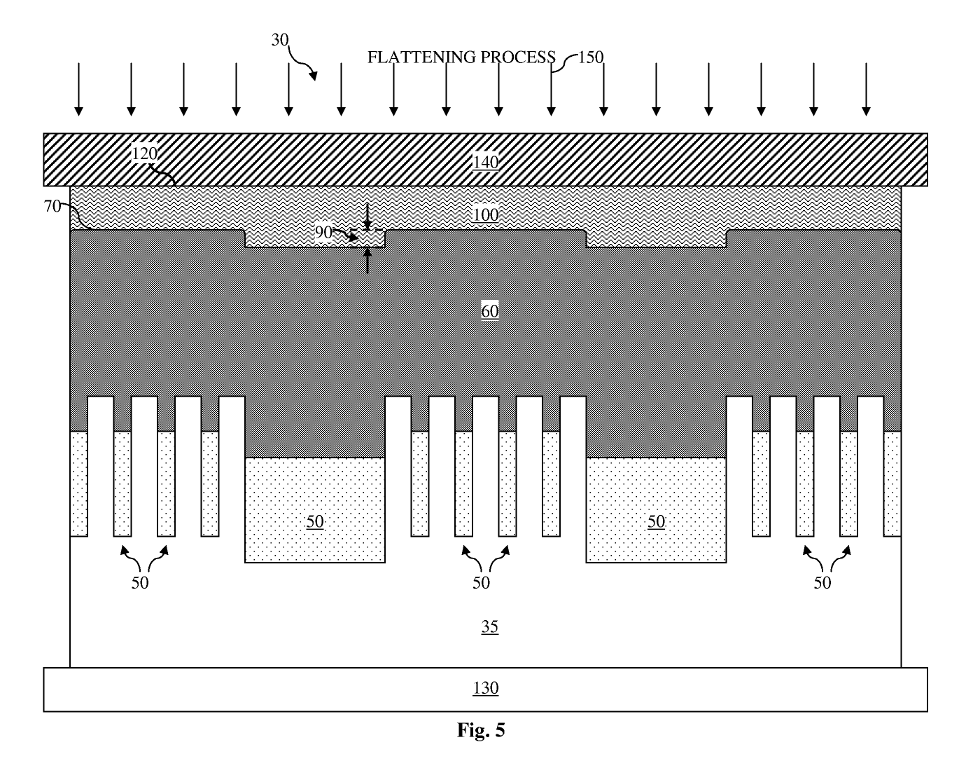

Referring to FIG. 5, the semiconductor wafer containing the semiconductor device 30 is placed on a supporting structure 130, for example a wafer chuck. It is understood that the wafer may have already been placed on the supporting structure 130 during (or even before) one of the previous fabrication stages. A flattening tool 140 is placed on the upper surface 120 of the material layer 100. Thereafter, a flattening process 150 is performed, which applies a mechanical force to push the flattening tool 140 against the surface 120. Stated differently, the flattening tool 140 applies a “downward” pressure to flatten the surface 120 of the material layer 100, since the material layer 100 is soft and malleable.

The flattening tool 140 has a substantially flat surface that is in contact with (or forms an interface with) the upper surface 120 of the material layer 100. In an embodiment, this substantially flat surface of the flattening tool 140 has a total surface variation (defined similarly to the total surface variation 90 discussed above in association with FIG. 3) that is less than about 10 angstroms. The flattening tool 140 may include a rotatable plate that rotates over different portions of the material layer 100 while the downward pushing force of the flattening process 150 is applied. Stated differently, the plate may be rotating while being pushed against the material layer 100. In this fashion, the upper surface 120 of the material layer 100 may become more planarized. Also, the flattening process 140 planarizes the upper surface 120 without removing any portion of the material layer 100.

In addition, a solvent may be added to the interface between the flattening tool 140 and the upper surface 120 of the material layer 100 during (or as a part of) the flattening process 150. The solvent may be a liquid, for example water. The solvent helps prevent the material layer 100 from sticking to the flattening tool 140. In other words, it is desirable to be able to easily remove the flattening tool 140 from the surface 120 once the flattening process 150 is completed. As such, the solvent is chosen so that it has phobic properties with respect to the interface formed between the flattening tool 140 and the upper surface 120 of the material layer 100, thereby reducing potential sticking. The flattening process 150 will cause the upper surface 120 of the material layer 100 to have a substantially planar or flat profile. In an embodiment, a total surface variation of the material layer 100 is less than about 10 angstroms.

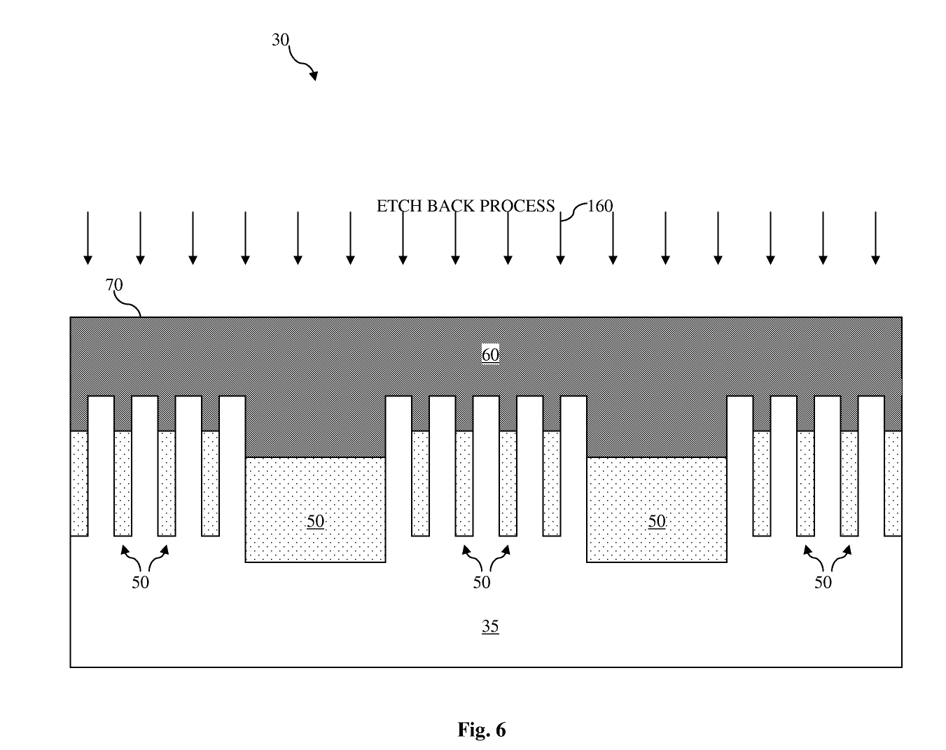

Referring to FIG. 6, after the flattening process 150 is completed, the flattening tool 140 is removed. Subsequently, an etch back process 160 (may also be referred to an etching back process) is performed on the semiconductor device 30 to remove the material layer 100 and a portion of the material layer 60. Since the material layer 100 is removed before subsequent fabrication processes are performed, it may be referred to as an intermediate layer.

The etch back process 160 is tuned in a manner such that it has an etching selectivity of substantially 1:1 with respect to the material layers 60 and 100. In other words, the material layers 60 and 100 have substantially identical etching rates. Thus, the material layers 60 and 100 may be etched away at the same rate, as if they are of the same material. In an embodiment, the etch back process 160 is a plasma dry etching process and includes the following process parameters (among others):
an etchant that includes a gas mixture of tetrafluoromethane (CF₄) and trifluoromethane (CHF₃), wherein a ratio of the CF₄ gas and the CHF₃ gas is in a range from about 0 to about 1;
a radio-frequency (RF) power that is in a range from about 200 watts to about 600 watts; and
a bias voltage from about 50 volts to about 250 volts.

As discussed above, due to the 1:1 etching selectivity of the etch back process 160, the material layer 60 and 100 are etched away at the same rate. In this manner, the substantially flat profile of the surface 120 of the material layer 100 (FIG. 5) is preserved and transferred to the upper surface 70 material layer 60 after the portion of the material 60 has been etched away. Therefore, the upper surface 70 of the material layer 60 also takes on a substantially flat or planar profile and may have a total surface variation that is less than about 10 angstroms.

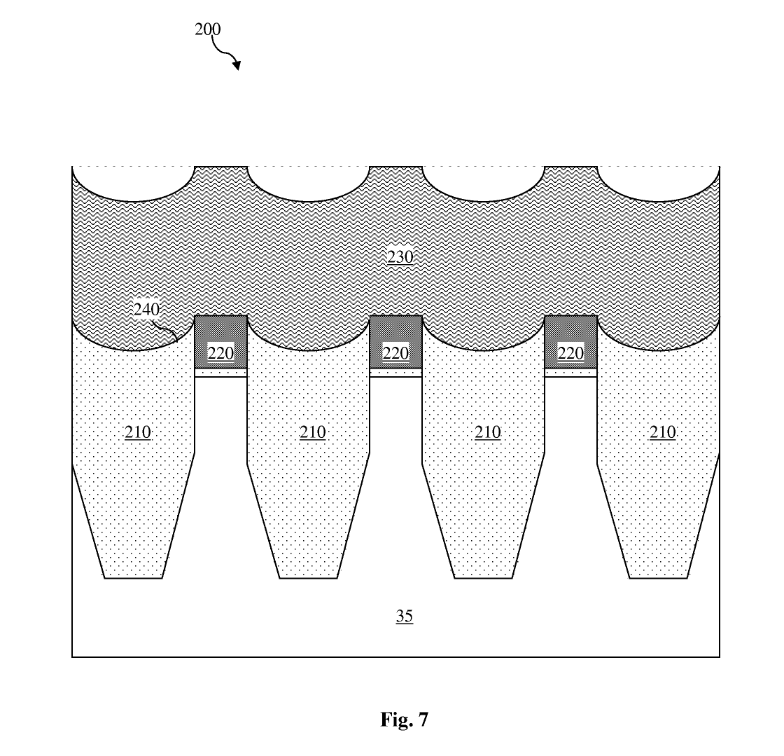

FIGS. 7-9 illustrate an alternative embodiment of the present disclosure at different fabrication stages. Referring to FIG. 7, an alternative semiconductor device 200 may be a portion of a semiconductor wafer. The semiconductor device 200 includes a substrate 35. A material layer 210 may be formed in the substrate 35. In an embodiment, the material layer 210 includes an oxide material. The material layer 210 may include dielectric isolation structures, such as shallow trench isolation (STI) structures. The STIs may be formed by etching recesses (openings) in the substrate 35 and then filling these openings with the dielectric material. Disposed between the upper regions of the STIs are hard mask portions 220 that are used to in the etching process as protective masks while the recesses of the STIs are etched into the substrate 35.

An optional CMP process similar to the CMP process 80 (shown in FIG. 3) may then be performed to thin the material layer 210. Thereafter, a material layer 230 similar to the material layer 100 discussed above with reference to FIGS. 2-6 is then formed over the material layer 210. The material layer 230 includes a soft and malleable material, which may be a photoresist material in an embodiment. The material layer 210 may have an upper surface 240 that is not planar enough for future processes. Thus, the material layer 230 serves as an intermediate layer in a manner similar to the material layer 100 discussed above with reference to FIGS. 2-6, so that substantial planarity of the upper surface 240 of the material layer 210 may be achieved.

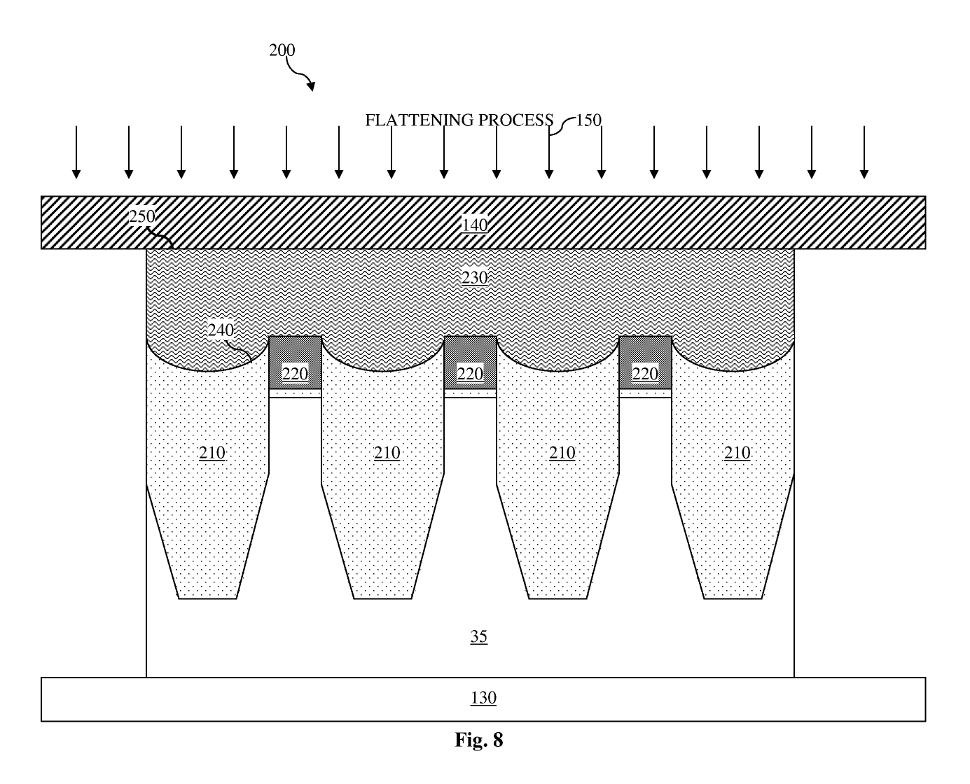

Referring now to FIG. 8, the flattening tool 140 is used again in the flattening process 150 to flatten an upper surface 250 of the material layer 230. Afterwards, the surface 250 of the material layer 230 may be substantially flat and can achieve a total surface variation of less than about 10 angstroms.

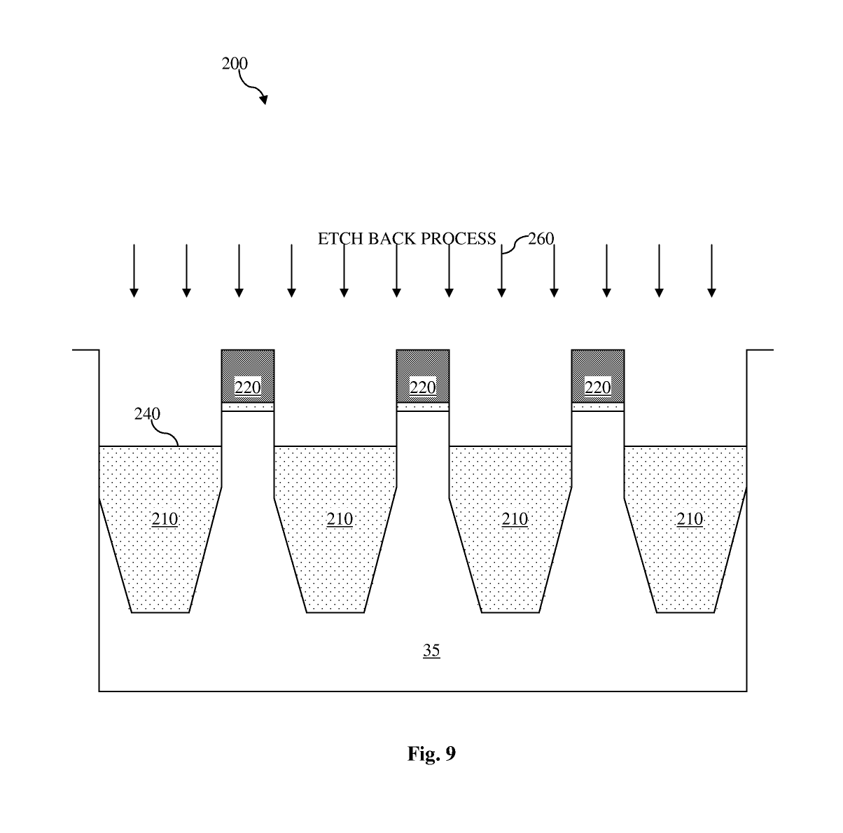

Referring now to FIG. 9, an etch back process 260 is performed on the semiconductor device 200 to etch away the material layer 230 and a portion of the material layer 210. The etch back process 260 is similar to the etch back process 160 (shown in FIG. 6). The etch back process 260 is tuned to have an etching selectivity of about 1:1 with respect to the material layers 210 and 230, which in an embodiment respectively include oxide and photoresist. In other words, in that embodiment, the etching process 260 ensures that a photoresist material has the same etching rate as an oxide material. Thus, the material layers 210 and 230 are etched away as if they belong to the same layer and have the same materials. In this manner, the substantial planarity of the surface 250 of the material layer 230 (both shown in FIG. 8) are preserved for the upper surface 240 of the material layer 210. Stated differently, after the etch back process 260, the upper surface 240 is substantially flat or planar, and may have a total surface variation of less than about 10 angstroms.

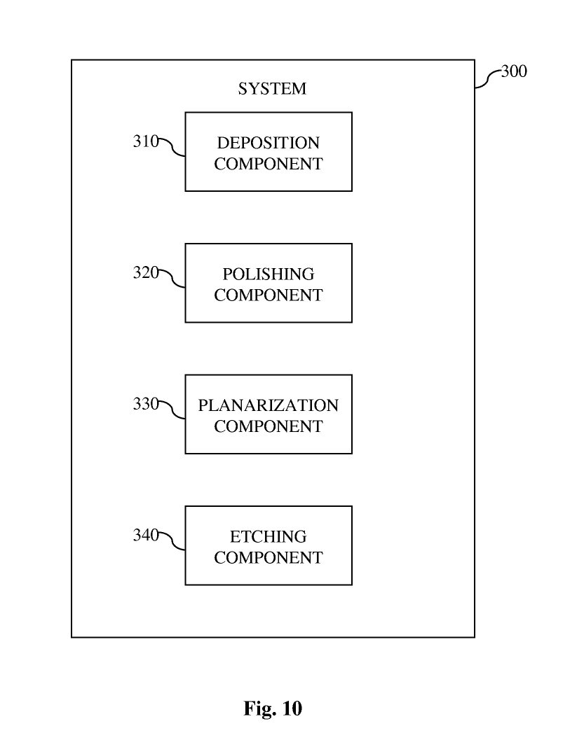

FIG. 10 illustrates a block diagram of a system 300 that can be used to carry out the planarization method discussed above in association with FIGS. 1-9. The system 300 includes a deposition component 310, a polishing component 320, a planarization component 330, and an etching component 340. The deposition component 310 may include one or more deposition tools such as CVD tools, PVD tools, ALD tools, or spin-coating tools. The deposition component 310 may be used to form the various layers such as the material layers 60, 100, 210, or 230. The polishing component 320 may include a CMP tool and can be used to perform the CMP process 80 (FIG. 3). The planarization component 330 may include the flattening tool 140 (FIGS. 5 and 8), a solvent or fluid dispenser that dispenses the solvent to prevent sticking between the flattening tool and layers therebelow, and other control tools that control the flattening tool. For example, the control tools may include a computer, a measurement tool, and/or a feedback loop mechanism. The etching component 340 may include etching tools such as an etching chamber that can be used to carry out the etch back processes 160 (FIG. 6) and 260 (FIG. 9).

The embodiments of the present disclosure discussed above have advantages over existing methods. It is understood, however, that other embodiments may have different advantages, and that no particular advantage is required for all embodiments. One of the advantages is that a substantially planar surface of a material layer (such as a polysilicon layer or a dielectric layer) may be achieved for cutting edge semiconductor fabrication technologies, such as for a 15 nanometer (nm) technology node or other technology nodes beyond the 15 nm node. The substantially planar surface may have a total surface variation of less than about 10 angstroms, which is much better than what can be achieved using existing planarization techniques.

Another advantage is that the embodiments disclosed herein are compatible with a Complementary Metal Oxide Semiconductor (CMOS) process flow. Thus, the embodiments disclosed herein can be implemented inexpensively and without causing significant disruptions for current fabrication process flows. As an example, the materials used for the intermediate layer may include photoresist, which can be easily formed using current fabrication equipment.

It is understood that additional processes may be performed to complete the fabrication of the semiconductor device 30 or 200. For example, the hard mask portions 220 (shown in FIG. 9) may be removed before further fabrication processes are performed. In addition, transistor devices may be formed in the semiconductor device 30 or 200. The wafers containing these semiconductor devices 30 and 200 may also undergo passivation, slicing, and packaging processes.

One of the broader forms of the present disclosure involves a method. The method includes: providing a substrate; forming a first material layer on the substrate; forming a second material layer over the first material layer, the second material layer being softer than the first material layer and having an exposed surface that is not in contact with the first material layer; flattening the second material layer without removing a portion of the second material layer, the flattening being carried out in a manner such that the exposed surface is substantially flat after the flattening; and performing an etch back process to remove the second material layer and a portion of the first material layer, wherein an etching selectivity of the etch back process with respect to the first and second material layers is approximately 1:1.

Another of the broader forms of the present disclosure involves a method. The method includes: providing a wafer; forming a malleable intermediate layer over at least a portion of the wafer; planarizing an exposed surface of the intermediate layer without removing a portion of the intermediate layer; and etching back the intermediate layer and the portion of the wafer, wherein a first etching rate of the intermediate layer is approximately the same as a second etching rate of the portion of the wafer being etched back.

Still another of the broader forms of the present disclosure involves a system. The system includes: a deposition component that forms a malleable intermediate layer on a wafer; a planarization component that planarizes an exposed surface of the intermediate layer; and an etching component that etches back the intermediate layer and a portion of the wafer, wherein a first etching rate of the intermediate layer is approximately the same as a second etching rate of the portion of the wafer being etched back.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
providing a substrate;
forming a first material layer on the substrate;
forming a second material layer over the first material layer, the second material layer being softer than the first material layer and having an exposed surface that is not in contact with the first material layer;
flattening the second material layer without removing a portion of the second material layer, the flattening being carried out in a manner such that the exposed surface is substantially flat after the flattening; and
performing an etch back process to remove the second material layer and a portion of the first material layer, wherein an etching selectivity of the etch back process with respect to the first and second material layers is approximately 1:1.

2. The method of claim 1, wherein the flattening includes applying a mechanical force against the exposed surface using a tool, wherein the tool has a substantially flat surface that is in contact with the exposed surface of the second material layer.

3. The method of claim 2, wherein the surface of the tool has a total surface variation less than approximately 10 angstroms.

4. The method of claim 2, wherein the tool includes a mechanical plate, and wherein the flattening further includes:
applying a solvent on one of: the surface of the tool and the exposed surface of the second material layer; and
rotating the plate over the exposed surface while the mechanical force is applied against the exposed surface.

5. The method of claim 1, wherein:
the forming the first material layer is carried out in a manner so that the first material layer includes one of: a polysilicon material and an oxide material; and
the forming the second material layer is carried out in a manner so that the second material layer includes a photoresist material.

6. The method of claim 1, wherein:
the forming the first material layer is carried out in a manner so that the first material layer has a total surface variation; and
the forming the second material layer is carried out in a manner so that the second material layer has a thickness that is greater than the total surface variation of the first material layer.

7. The method of claim 1, further including, before the forming the second material layer, performing a chemical-mechanical-polishing (CMP) process on the first material layer.

8. The method of claim 1, wherein the etch back process includes the following parameters:
an etchant that includes a gas mixture of tetrafluoromethane (CF₄) and trifluoromethane (CHF₃), a ratio of the CF₄ gas and the CHF₃ gas being in a range from about 0 to about 1;
a radio-frequency (RF) power that is in a range from about 200 watts to about 600 watts; and
a bias voltage that is in a range from about 50 volts to about 250 volts.

9. A method, comprising:
providing a wafer;
forming a malleable intermediate layer over at least a portion of the wafer;
planarizing an exposed surface of the intermediate layer without removing a portion of the intermediate layer; and
etching back the intermediate layer and the portion of the wafer, wherein a first etching rate of the intermediate layer is approximately the same as a second etching rate of the portion of the wafer being etched back.

10. The method of claim 9, wherein the planarizing includes pressing a substantially flat-surfaced mechanical object against the exposed surface of the intermediate layer.

11. The method of claim 10, wherein the mechanical object includes a mechanical plate that has a surface flatness variation that is less than about 10 angstroms, and wherein the planarizing further includes:
introducing a fluid to an interface between the mechanical plate and the exposed surface of the intermediate layer, the fluid being phobic to the interface; and
moving the plate across the exposed surface during the pressing.

12. The method of claim 9, wherein:
the portion of the wafer that is etched back includes one of: a semiconductor material and a dielectric material; and
the intermediate layer includes a photoresist material that has not been hard baked.

13. The method of claim 9, wherein the intermediate layer has a thickness that is in a range from approximately 500 angstroms to approximately 1500 angstroms.

14. The method of claim 9, further including, before the forming the intermediate layer, polishing the wafer.

15. A system, comprising:
a planarization component that planarizes an exposed surface of a malleable intermediate layer formed on a wafer, wherein the planarization component carries out the planarizing without removing a portion of the intermediate layer; and
an etching component that etches back the intermediate layer and a portion of the wafer, wherein a first etching rate of the intermediate layer is approximately the same as a second etching rate of the portion of the wafer being etched back.

16. The system of claim 15, wherein the planarization component includes a plate having a substantially smooth surface that is pressed against the exposed surface of the intermediate layer.

17. The system of claim 16, wherein the substantially smooth surface of the plate has a total surface variation that is less than approximately 10 angstroms.

18. The system of claim 16, wherein the planarization component further includes a fluid dispenser that dispenses a fluid to an interface formed by the plate and the exposed surface of the intermediate layer, the fluid being phobic to the interface; and wherein the plate rotates around the exposed surface.

19. The system of claim 15, further including:
a polishing component that is operable to perform a chemical-mechanical-polishing (CMP) process on the wafer before the intermediate layer is formed on the wafer; and
a deposition component that is operable to form the intermediate layer on the wafer after the polishing.

20. The system of claim 15, wherein the etching component etches back the intermediate layer and a portion of the wafer by using the following process parameters:
an etchant that includes a gas mixture of tetrafluoromethane (CF₄) and trifluoromethane (CHF₃), a ratio of the CF₄ gas to the CHF₃ gas being less than about 1:1;
a bias voltage that is in a range from about 50 volts to about 250 volts; and
a radio-frequency (RF) power that is in a range from about 200 watts to about 600 watts.
